(19) United States
(12) Patent Application Publication
(10) Pub. No.: US 2025/0022694 A1
(43) Pub. Date: Jan. 16, 2025

(54) HEATER PLATES WITH DISTRIBUTED PURGE CHANNELS, RF MESHES AND GROUND ELECTRODES

(71) Applicant: Applied Materials, Inc., Santa Clara, CA (US)

(72) Inventors: Pranav Vijay Gadre, Sunnyvale, CA (US); Adib M. Khan, San Jose, CA (US); Qiwei Liang, Fremont, CA (US); Dmitry Lubomirsky, Cupertino, CA (US); Hyun Joo Lee, San Jose, CA (US); Paneendra Prakash Bhat, Sunnyvale, CA (US); Douglas A. Buchberger, JR., Livermore, CA (US); Onkara Swamy Korasiddaramaiah, Fremont, CA (US); Vijay D. Parkhe, San Jose, CA (US); Junghoon Kim, Santa Clara, CA (US); Kallol Bera, Fremont, CA (US); Rupali Sahu, Milpitas, CA (US); Sathya Swaroop Ganta, Sunnyvale, CA (US)

(21) Appl. No.: 18/762,865

(22) Filed: Jul. 3, 2024

Related U.S. Application Data
(60) Provisional application No. 63/526,504, filed on Jul. 13, 2023.

(51) Int. Cl. H01J 37/32; C23C 16/44; C23C 16/455; C23C 16/458; C23C 16/46; C23C 16/509; H05B 6/54; H05B 6/62

(52) U.S. Cl. CPC H01J 37/32724; C23C 16/4408; C23C 16/45565; C23C 16/4586; C23C 16/46; C23C 16/509; H01J 37/32091; H01J 37/3244; H01J 37/32568; H01J 37/32577; H01J 37/32834; H05B 6/54; H05B 6/62; H01J 2237/20235; H01J 2237/332

(57) ABSTRACT

A substrate support assembly includes a heater plate including a dielectric material, a heater electrode embedded within the heater plate, a set of distributed purge channels formed within the heater plate, wherein the set of distributed purge channels provides a set of gas flow paths to equalize a gas flow from within the heater plate and direct the gas flow in a direction below the heater plate, a ground electrode embedded within the heater plate, and a radio frequency (RF) mesh embedded within the plate.

The present application claims the benefit of U.S. Provisional Application 63/526,504, filed on Jul. 13, 2023 and entitled “HEATER PLATES WITH DISTRIBUTED PURGE CHANNELS, RF MESHES AND GROUND ELECTRODES”, the entire contents of which are hereby incorporated by reference herein.

### TECHNICAL FIELD

Embodiments of the present invention relate, in general, to substrate processing, and in particular, to heater plates with distributed purge channels, RF meshes and ground electrodes.

### BACKGROUND

Reliably producing nanometer and smaller features is one technological challenge for next generation very large scale integration (VLSI) and ultra large-scale integration (ULSI) of electronic devices (e.g., semiconductor devices). However, as the limits of circuit technology are pushed, the shrinking dimensions of VLSI and ULSI interconnect technology have placed additional demands on processing capabilities. Reliable formation of gate structures on the substrate is important to VLSI and ULSI success and to the continued effort to increase circuit density and quality of individual substrates and die. To drive down manufacturing cost, integrated chip (IC) manufacturers demand higher throughput and better device yield and performance from every substrate processed. Some substrate processing techniques are performed at temperatures above 300° C.

### SUMMARY

In some embodiments, a substrate support assembly is provided. The substrate support assembly includes a heater plate including a dielectric material, a heater electrode embedded within the heater plate, a set of distributed purge channels formed within the heater plate, wherein the set of distributed purge channels provides a set of gas flow paths to equalize a gas flow from within the heater plate and direct the gas flow in a direction below the heater plate, a ground electrode embedded within the heater plate, and a radio frequency (RF) mesh embedded within the plate.

In some embodiments, a system is provided. The system includes a showerhead assembly including a set of lift pins to receive a substrate over the showerhead assembly, and a showerhead to deliver one or more process gases to perform a deposition process to deposit a material on a backside of the substrate. The system further includes a substrate support assembly disposed above the showerhead assembly. The substrate support assembly includes a shaft, a heater plate disposed on the shaft and including a dielectric material, a set of distributed purge channels formed within the heater plate, wherein the set of distributed purge channels provides a set of gas flow paths to equalize a gas flow from within the heater plate and direct the gas flow in a direction below the heater plate, a ground electrode embedded within the heater plate, and a radio frequency (RF) mesh embedded within the heater plate.

In some embodiments, a method is provided. The method includes obtaining a substrate within a processing chamber, and performing a deposition process within the processing chamber using a substrate support assembly to form material on the substrate with non-contact heating. The substrate support assembly includes a heater plate including a dielectric material, a heater electrode embedded within the heater plate, a set of distributed purge channels formed within the heater plate, wherein the set of distributed purge channels provides a set of gas flow paths to equalize a gas flow from within the heater plate and direct the gas flow in a direction below the heater plate, a ground electrode embedded within the heater plate, and a radio frequency (RF) mesh embedded within the plate.

Numerous other aspects and features are provided in accordance with these and other embodiments of the disclosure. Other features and aspects of embodiments of the disclosure will become more fully apparent from the following detailed description, the claims, and the accompanying drawings.

### BRIEF DESCRIPTION OF THE DRAWINGS

Embodiments described herein are illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a diagram of a cross-sectional view of an example substrate processing system including a processing chamber and a substrate support assembly, in accordance with some embodiments.

FIGS. 2A-2B are diagrams of cross-sectional views example substrate support assemblies including a heater plate with distributed purge channels, a radio frequency (RF) mesh and a ground electrode, in accordance with some embodiments.

FIG. 2C is a diagram of a top-down view of an example configuration of distributed purge channels of a heater plate, in accordance with some embodiments.

FIG. 2D is a diagram of a top-down cross-sectional view of an example radio frequency (RF) connector of a substrate support assembly, in accordance with some embodiments.

FIGS. 3A-3B are diagrams of cross-sectional views of porous plugs that can be included in distributed purge channels of heater plates, in accordance with some embodiments.

FIG. 4 is a flowchart of an example method for fabricating substrate support assemblies including heater plates with distributed purge channels, radio frequency (RF) meshes and ground electrodes, in accordance with some embodiments.

FIG. 5 is a flowchart of an example method for processing substrates within a processing chamber using a substrate support assembly including a heater plate with distributed purge channels, a radio frequency (RF) mesh and a ground electrode, in accordance with some embodiments.

### DETAILED DESCRIPTION OF EMBODIMENTS

Described herein are embodiments of heater plates with distributed purge channels, RF meshes and ground electrodes as well as fabrication of such heater plates. Some processing chambers can include substrate support assemblies that can include heater plates to control heating and/or temperature during substrate processing. A heater plate can include a set of heater electrodes embedded therein to heat a substrate to a target temperature or temperature range during a manufacturing process, such as deposition, etching and/or lithography. The temperature of the heater plate can be controlled by a temperature controller coupled to the set of heater electrodes by regulating the power supplied to the set of heater electrodes. The temperature controller can enable precise control of the temperature of the substrate within a target range to optimize the manufacturing process being performed.

Purge flow may be used to purge unwanted process gases, such as deposition gases. However, uniformity of purge flow to the substrate can be challenging for some processes, such as deposition processes. Moreover, during some deposition processes, such as plasma deposition processes, unwanted material may be deposited on processing chamber surfaces. One example of a deposition process is a backside deposition process in which material is deposited on the backside of a substrate.

To address at least the above-noted drawbacks, embodiments described herein provide for heater plates with distributed purge channels, RF meshes and ground electrodes. For example, a substrate support assembly (e.g., heater assembly) can include a heater plate disposed on a shaft. The heater plate can be formed from a dielectric material. In some embodiments, the heater plate is a ceramic heater plate formed from a ceramic material. For example, the dielectric material can include aluminum nitride (AlN), aluminum oxide or alumina (Al₂O₃), etc.

The heater plate can include a set of heater electrodes embedded therein. The heater plate can enable high-temperature operation. In some embodiments, the heater plate enables heating of substrates to temperatures greater than or equal to 500° C. In some embodiments, the heater plate enables heating to temperatures greater than or equal to 600° C. In some embodiments, the heater plate enables heating to temperatures greater than or equal to 700° C. In some embodiments, the heater plate is a single zone heater plate. In some embodiments, the heater plate is a multi-zone heater plate. For a multi-zone heater plate, the heater plate may be divided into multiple zones, each including a separately controllable heating electrode or set of heating electrodes (e.g., resistive heating elements). Accordingly, different heating may be applied to different zones.

A substrate support assembly can support the performance of a deposition process from a first side of a substrate by providing purge flow to a second side of the substrate opposite the first side. In some embodiments, the first side of the substrate is the backside (e.g., backside deposition process) and the second side of the substrate is the frontside (e.g., frontside purging). For example, a backside deposition chamber can include a showerhead assembly positioned to face the backside of a substrate and the heater plate facing the frontside of the substrate. A material can be deposited on the backside of the substrate to form a backside material (e.g., film) through any suitable deposition process. For example, the deposition process can be a chemical vapor deposition (CVD) process. In some embodiments, the CVD process is a plasma-enhanced CVD process (PECVD). A PECVD process refers to a CVD process that uses a plasma to create a reactive species used to deposit material. For example, the CVD process can be a capacitively coupled plasma (CCP) process. A CCP process can use a capacitively coupled plasma to create the reactive species. In a CCP deposition chamber, the substrate is placed between two electrodes, and a high-frequency RF power source is applied to the electrodes to create an electric field between the electrodes. The electric field ionizes process gases in the chamber which react with each other to form the material. A PECVD process such as a CCP process can be a low-temperature process, which can be beneficial in applications involving materials that can be damaged by high temperatures. In some embodiments, the backside material provides stress compensation and controls substrate bow profile resulting from processing to be performed with respect to the frontside of the substrate.

Additionally, contact between the heater plate and the frontside of the substrate should be minimized to prevent defect formation (e.g., scratches or particles). To accomplish this, a gap can be provided between the heater plate and the substrate during the deposition process. In some embodiments, the gap ranges from about 0.5 millimeter (mm) to about 3 mm. To ensure good material quality and post-anneal stress retention, the substrate can be heated to a sufficiently high temperature. In some embodiments, the substrate is heated to a temperature that ranges between about 450° C. to about 650° C. In some embodiments, the substrate is heated to a temperature of about 500° C.

To prevent deposition of material on the frontside of the substrate during the backside deposition process, the frontside of the substrate can be purged to vacate any unwanted deposition chemistries. To achieve this, distributed purge channels can be formed within the heater plate to provide uniform purge flow through the heater plate. More specifically, the distributed purge channels can be included in gas paths in the heater plate, and the shaft can include a set of gas inlets to a purge plenum. A purge plenum is a chamber or enclosure in a gas distribution system that can be used to provide a clean and controlled environment for purge gas flow. In a purge plenum, the purge gases can be introduced into a chamber that is separated from the main gas delivery line by a gas-tight barrier. The purge gas flows through a series of channels or holes in the barrier and into the main gas delivery line, ensuring that the gas is delivered in a controlled and uniform manner. The purge plenum also serves to remove any impurities or contaminants from the gas, helping to ensure that the gas is of a high purity and quality. The purge plenum can be equipped with monitoring equipment (e.g., sensors) to ensure that the gas flow is consistent and to detect any leaks or other issues that may arise during operation.

In some embodiments, the gas paths can be recursive gas paths. A recursive gas path is a gas path that branches out over multiple levels. For example, a single inlet path (e.g., source path) can split into two outlet paths. Each of the two branch paths then further split into two additional outlet paths, etc. By using recursive gas paths, gas flow can be evenly distributed from a single inlet (e.g., source) into multiple outlets (e.g., at least four to provide good flow uniformity through each of the outlet paths. In some embodiments, the set of gas inlets includes four gas inlets.

In some embodiments, porous plugs can be formed in each of the purge channels to reduce plasma formation and/or arcing to prevent damage to the heater plate and/or the substrate. For example, a porous plug can prevent the ionization of a purge gas by convoluting a gas path and reducing empty volume in the heater plate. The purge flow can enable high pressure buildup over the substrate to prevent plasma light up and to prevent process gas diffusion toward the center of the substrate. In some embodiments, a porous plug is press fit into a purge channel. In some embodiments, a porous plug is secured within a porous plug using an adhesive. In some embodiments, a porous plug has a conical or tapered profile to secure the porous plug within a purge channel, with a diameter that gets smaller toward the substrate.

If a deposition process such as CCP is used for deposition, then the heater plate can serve as an RF powered electrode. To do so, the heater plate can further include an RF mesh embedded therein that can be biased with symmetric RF delivery for improved deposition uniformity. For example, the RF mesh can be located toward the upper surface of the heater plate. The RF mesh can include any suitable material in accordance with embodiments described herein.

The heater plate can further include a ground electrode embedded therein to prevent deposition of unwanted material on processing chamber surfaces. For example, the ground electrode can shield the processing chamber surfaces from the potential on the heater plate while driving electric fields and plasma towards the substrate for deposition. The ground electrode can be located between the set of heater electrodes and the RF mesh.

The RF mesh and the ground electrode can be connected by an RF connector through the interior of the shaft (e.g., the center of the shaft). For example, the RF connector be an RF coax connector including an RF feed that can enable symmetric RF delivery.

The heater plate can further include a hole for a thermocouple to provide temperature feedback. The heater plate can further include an edge electrode. The edge electrode can enable plasma profile control. An edge electrode pin can be disposed between the edge electrode and the RF mesh. In some embodiments, the edge electrode is electrically connected to the RF mesh. In some embodiments, the edge electrode is electrically isolated and powered independently of the RF mesh.

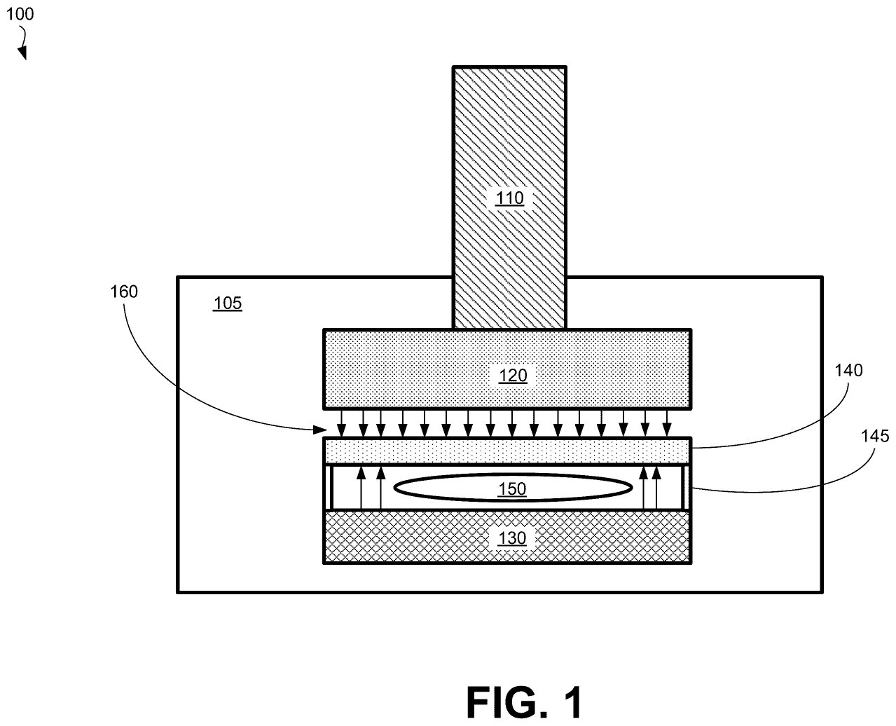

Embodiments described herein can provide numerous advantages. For example, the gap between the substrate and the heater plate can enable non-contact heating of the substrate during processing (e.g., backside deposition processes). As another example, the set of distributed purge channels can enable efficient purging of process gases during substrate processing. As yet another example, the RF connector (e.g., RF coax) can enable symmetric RF delivery. As yet another example, the ground electrode can prevent deposition of unwanted material on processing chamber surfaces. As yet another example, the use of an RF mesh can enable the heater plate to serve as an RF powered electrode during processing (e.g., a CCP deposition process). Further details regarding heater assemblies including heater plates with distributed purge channels, RF meshes and ground electrodes are described herein below with reference to FIGS. 1-5.

FIG. 1 is a cross-sectional side view of a substrate processing system (“system”) 100, in accordance with some embodiments. As shown, system 100 can include processing chamber 105 and a substrate support assembly including shaft 110 and heater plate 120 disposed on shaft 110. More specifically, processing chamber 105 is a deposition chamber including showerhead assembly 130 that can be used to deposit material on substrate 140. Substrate 140 can be placed on set of lift pins including lift pin 145.

More specifically, in this illustrative example, system 100 supports a backside deposition process in which material is deposited on the backside of substrate 140. In some embodiments, the backside deposition process is a plasma-enhanced deposition process. More specifically, plasma 150 can be generated in a region between showerhead assembly 130 and the backside of substrate 140. In some embodiments, the backside deposition process is a PECVD process. For example, the backside deposition process can be a CCP process.

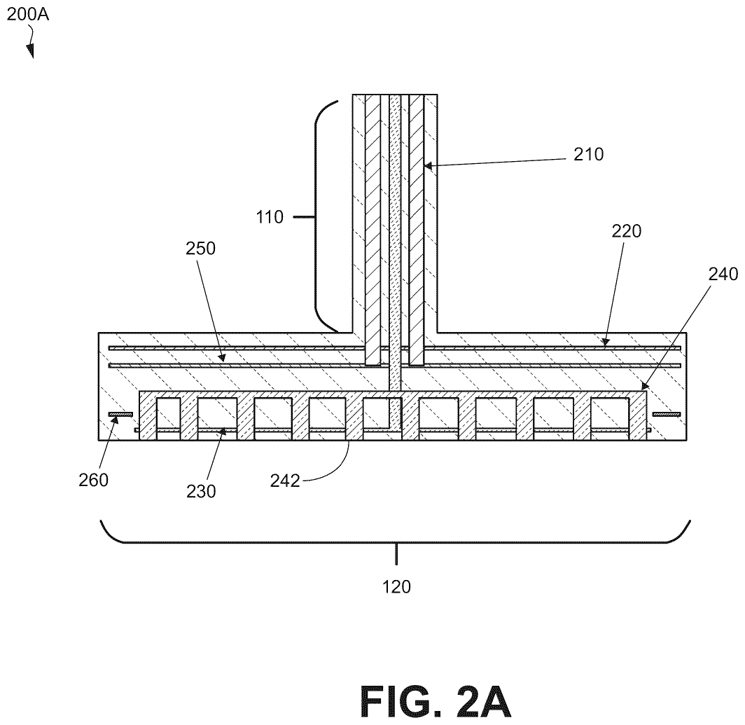

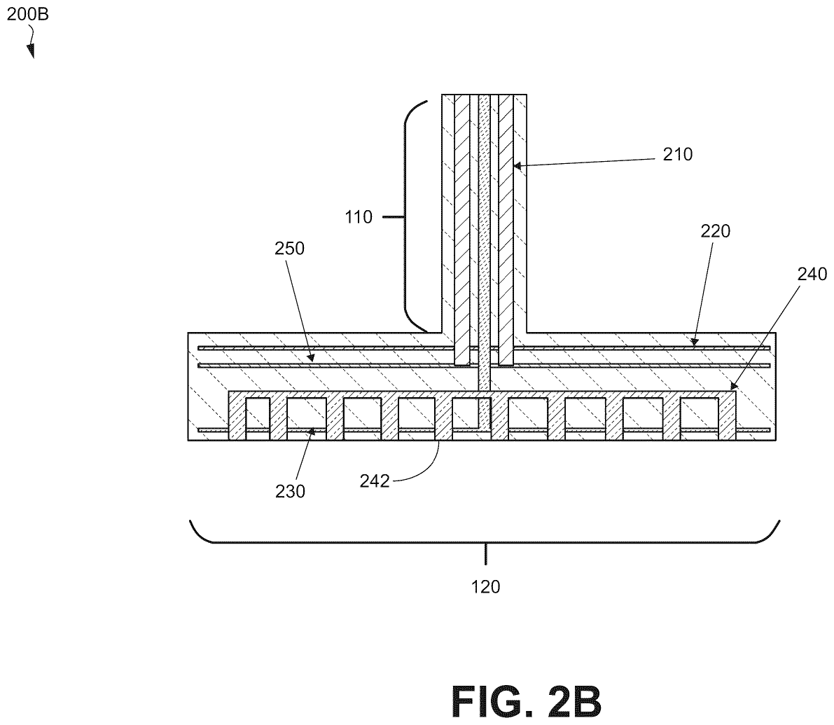

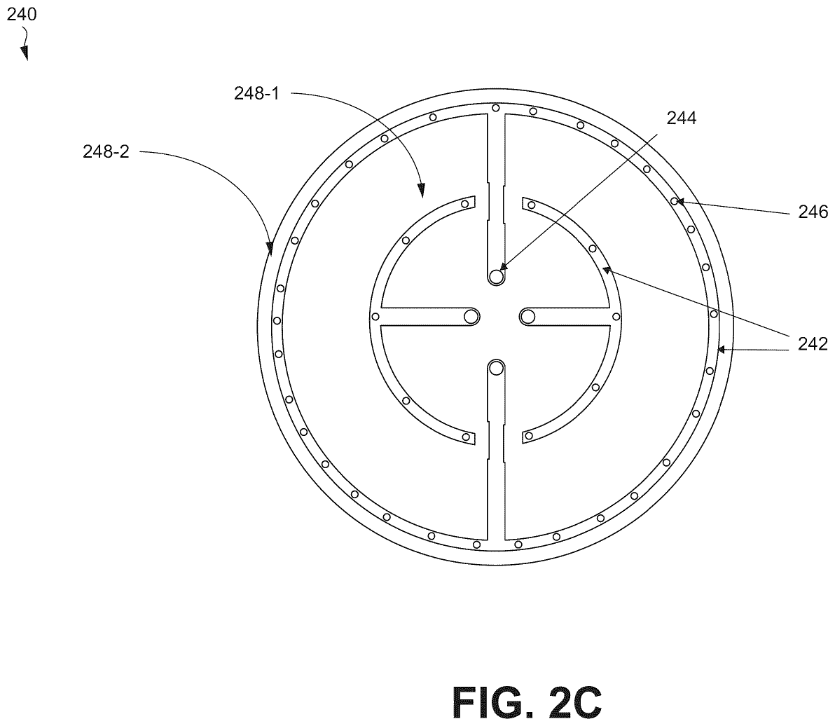

Heater plate 120 can heat substrate 140 during processing (as indicated by the arrows directed toward the frontside of substrate 140). Heater plate 120 can be formed from a dielectric material. In some embodiments, the heater plate 120 is formed from a ceramic material. For example, the dielectric material can include AlN, Al₂O₃, etc. Heater plate 120 can include a set of heater electrodes embedded therein (not shown in FIG. 1). Heater plate 120 can enable high-temperature operation. In some embodiments, heater plate 120 enables heating at temperatures greater than or equal to 500° C. In some embodiments, heater plate 120 enables heating at temperatures greater than or equal to 600° C. In some embodiments, heater plate 120 enables heating at temperatures greater than or equal to 700° C. In some embodiments, heater plate 120 is a single zone heater plate. Further details regarding the set of heater electrodes will be described below with reference to FIG. 2A.

In some embodiments, gap 160 is provided between heater plate 120 and substrate 140 to prevent defect formation (e.g., scratches or particles) by enabling non-contact heating. In some embodiments, gap 160 ranges from about 0.5 mm to about 3 mm. To ensure sufficiently good material quality and post-anneal stress retention, substrate 140 can be heated to a sufficiently high temperature. In some embodiments, substrate 140 is heated to a temperature that ranges between about 450° C. to about 650° C. In some embodiments, substrate 140 is heated to a temperature of about 500° C.

To prevent deposition of material on the frontside of substrate 140 during the backside deposition process, the frontside of substrate 140 can be purged to vacate any unwanted deposition chemistries during processing. To achieve this, a purge gas can be delivered through shaft 110 and released through heater plate 120 over the upper surface of substrate 140. For example, a set of distributed purge channels (not shown in FIG. 1) can be formed within heater plate 120 to provide uniform purge flow through heater plate 120. More specifically, the set of distributed purge channels can provide a set of gas paths in heater plate 120. For example, the set of gas paths can be a set of recursive gas paths including a set of gas inlets and a set of gas outlets. In some embodiments, the set of gas inlets includes four gas inlets.

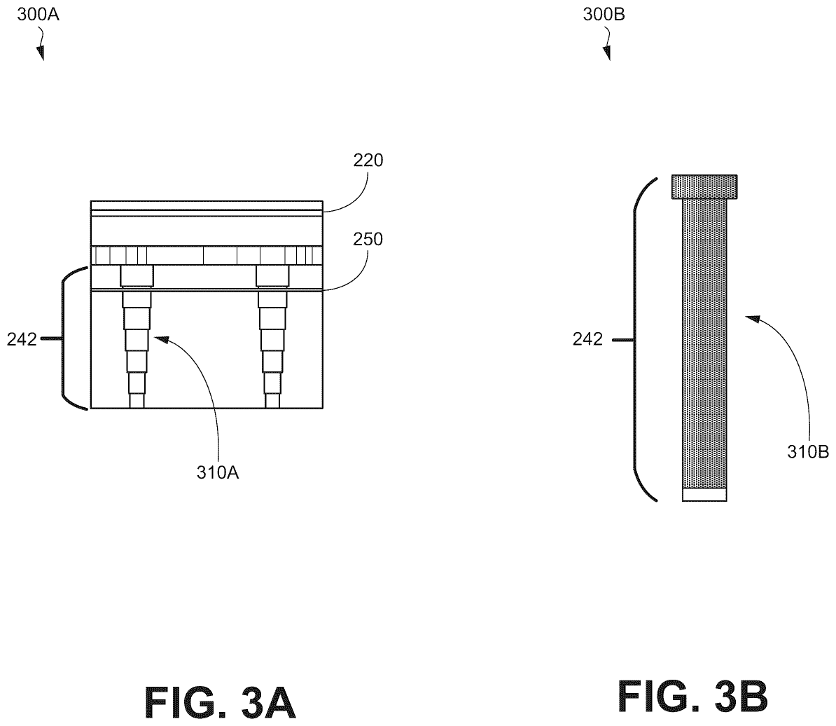

Additionally, heater plate 120 can include porous plugs formed in the purge channels (not shown in FIG. 1) to reduce plasma formation and/or arcing to prevent damage to heater plate 120 and/or substrate 140. For example, the porous plugs can prevent the ionization of the purge gas by convoluting the gas path and reducing empty volumes in heater plate 120. The purge flow can enable high pressure buildup over substrate 140 to prevent plasma light up and to prevent process gas diffusion toward the center of substrate 140. In some embodiments, a porous plug is press fit into a purge channel. In some embodiments, a porous plug is secured within a porous plug using an adhesive. In some embodiments, a porous plug has a conical or tapered profile to secure the porous plug within a purge channel, with a diameter that gets smaller toward the substrate. Further details regarding the distributed purge channels and the porous plugs will be described below with reference to FIGS. 2A-3B.

In some embodiments, heater plate 120 serves as an RF powered electrode. More specifically, heater plate 120 plate can include an RF mesh embedded therein (not shown in FIG. 1) that can be biased with symmetric RF delivery for improved deposition uniformity. For example, the RF mesh can be located toward the upper surface of heater plate 120. Further details regarding the RF mesh will be described below with reference to FIG. 2A.

In some embodiments, heater plate 120 can further include a ground electrode embedded therein (not shown in FIG. 1) to prevent deposition of unwanted material on surfaces of processing chamber 105. For example, the ground electrode can shield the surfaces of processing chamber 105 from the potential on heater plate 120 while driving electric fields and plasma towards substrate 140 for deposition. The ground electrode can be located between the set of heater electrodes and the RF mesh. Further details regarding the ground electrode will be described below with reference to FIG. 2A.

The RF mesh and the ground electrode can be connected by an RF connector through the interior of shaft 110 (e.g., the center of the shaft) (not shown in FIG. 1). For example, the RF connector be an RF coax connector including an RF feed that can enable symmetric RF delivery. Further details regarding the RF connector will be described below with reference to FIGS. 2A and 2C.

Heater plate 120 can further include a hole for a thermocouple to provide temperature feedback (not shown in FIG. 1). Heater plate 120 can further include an edge electrode (not shown in FIG. 1). The edge electrode can enable plasma profile control. An edge electrode pin can be disposed between the edge electrode and the RF mesh. In some embodiments, the edge electrode is electrically connected to the RF mesh. In some embodiments, the edge electrode is electrically isolated and powered independently of the RF mesh. Further details regarding substrate support assemblies including heater plates with distributed purge channels, RF meshes and ground electrodes are described herein below with reference to FIGS. 1-4.

FIG. 2A is a diagram of a cross-sectional view of an example substrate support assembly 200AA, in accordance with some embodiments. As shown, substrate support assembly 200AA can include shaft 110 and heater plate 120 disposed on shaft 110, similar to shaft 110 and heater plate 120 described above with reference to FIG. 1. For example, substrate support assembly 200A can be used in system 100 of FIG. 1 during a deposition process (e.g., backside deposition process) performed to deposit material on a substrate (e.g., on a backside of substrate 140 of FIG. 1). In some embodiments, substrate 140 is a circular substrate. For example, substrate may be a wafer such as a semiconductor wafer. In some embodiments, substrate 140 is a non-circular substrate (e.g., rectangular substrate). For example, substrate may be a rectangular display or glass sheet.

As further shown, substrate support assembly 200A can include RF connector 210, set of heater electrodes including heater electrode 220 embedded within heater plate 120, RF mesh 230 embedded within heater plate 120, set of distributed purge channels 240 including purge channel 242 formed within heater plate 120, and ground electrode 250 embedded within heater plate 120.

In some embodiments, heater plate 120 enables heating at temperatures greater than or equal to 500° C. In some embodiments, heater plate 120 enables heating at temperatures greater than or equal to 600° C. In some embodiments, heater plate 120 enables heating at temperatures greater than or equal to 700° C. In some embodiments, heater plate 120 is a single zone heater plate.

As described above with reference to FIG. 1, RF mesh 230 can enable heater plate 120 to serve as an RF powered electrode. More specifically, RF mesh 230 can enable heater plate 120 to be biased with symmetric RF delivery for improved deposition uniformity. For example, as shown in FIG. 2A, RF mesh 230 can be located toward the upper surface of heater plate 120. RF mesh 230 can include any suitable material in accordance with embodiments described herein. In some embodiments, RF mesh 230 includes molybdenum (Mo). In some embodiments, RF mesh 230 includes an alloy. For example RF mesh 230 can include a suitable ferrous alloy.

As described above with reference to FIG. 1, set of distributed purge channels 240 can be used to purge unwanted deposition chemistries during deposition to prevent deposition of material on a first side (e.g., front side) of a substrate during a deposition process that forms material on a second side (e.g., back side) of the substrate opposite the first side. In some embodiments, the first side is a frontside and the second side is a backside. More specifically, set of distributed purge channels 240 can enable uniform purge flow through heater plate 120. More specifically, set of distributed purge channels 240 can include recursive gas paths, and shaft 110 can include a set of gas inlets to a recursive purge plenum. In some embodiments, the set of gas inlets includes four gas inlets. In some embodiments, a porous plug is formed in each purge channel of set of distributed purge channels 240. The porous plugs can be used to reduce plasma formation and/or arcing to prevent damage to heater plate 120 and/or the substrate. For example, the porous plugs can prevent the ionization of the purge gas by convoluting the gas path and reducing empty volumes in the heater plate. The purge flow can enable high pressure buildup over the substrate to prevent plasma light up and to prevent process gas diffusion toward the center of the substrate. In some embodiments, a porous plug is press fit into a purge channel. In some embodiments, a porous plug is secured within a porous plug using an adhesive. In some embodiments, a porous plug has a conical or tapered profile to secure the porous plug within a purge channel, with a diameter that gets smaller toward the substrate. Further details regarding the distributed purge channels and the porous plugs will be described below with reference to FIGS. 2C and 3A-3B.

As described above with reference to FIG. 1, ground electrode 250 can be used to prevent deposition of unwanted material on processing chamber surfaces. For example, ground electrode 250 can shield the processing chamber surfaces from the potential on heater plate 120 while driving electric fields and plasma towards the substrate for deposition. For example, as shown in FIG. 2A, ground electrode 250 can be located between heater electrode 220 and RF mesh 230.

RF mesh 230 and ground electrode 250 can be connected by RF connector 210 through the interior of shaft 110 (e.g., the center of the shaft). For example, RF connector 210 can be an RF coax connector including an RF feed that can enable symmetric RF delivery. Further details regarding the RF connector will be described below with reference to FIG. 2C.

Heater plate 120 can further include a hole for a thermocouple to provide temperature feedback (not shown in FIG. 2A). In some embodiments edge electrode 260 is embedded within heater plate 120. Edge electrode 260 can enable plasma profile control. An edge electrode pin (not shown) can be disposed between edge electrode 260 and RF mesh 230. In these embodiments, edge electrode 260 is electrically connected to RF mesh 230. In alternative embodiments, edge electrode 260 is electrically isolated and powered independently of RF mesh 230.

The arrangement of the electrodes embedded within heater plate 120 should not be considered limiting. In some embodiments, and as shown in FIG. 2A, heater electrode 220 is located above ground electrode 250. In other embodiments, heater electrode 220 is located underneath ground electrode 250.

FIG. 2B is a diagram of a cross-sectional view of an example substrate support assembly 200B, in accordance with some embodiments. Substrate support assembly 200B is similar to substrate support assembly 200A, except that it does not include edge electrode 260. Moreover, RF mesh 230 extends to be approximately coterminal with electrodes 220 and 250. Further details regarding substrate support assembly 200A of FIG. 2A and substrate support assembly 200B of FIG. 2B will now be described below with reference to FIGS. 2C-4.

FIG. 2C is a diagram of a top-down view of an example configuration of set of distributed purge channels 240 including purge channels 242, in accordance with some embodiments. As further shown in FIG. 2C, set of distributed purge channels 240 can include gas inlets (“inlets”) including inlet 244 and gas outlets (“outlets”) including outlet 246. More specifically, set of distributed purge channels 240 can include inner zone 248-1 and outer zone 248-2. A purge gas may flow into the substrate support assembly from gas inlets 244, may be distributed within the substrate support assembly via the purge channels 242, and may flow out of the substrate support assembly and towards a substrate disposed beneath the substrate support assembly via gas outlets 246. The gas outlets in the inner and outer zones 248-1 and 248-2 enable a constant flow of inert gas towards the front side of a substrate during deposition on a backside of the substrate to prevent deposition on the front side of the substrate in embodiments.

FIG. 2D is a diagram of a top-down cross-sectional view of RF connector 210, in accordance with some embodiments. As shown in FIG. 2D, RF connector 210 can include RF rod 212 and outer shield 214. RF rod 212 and outer shield 214 can be formed from any suitable materials. In some embodiments, RF rod 212 is formed from quartz. In some embodiments, outer shield 214 is formed from Mo.

FIG. 3A is a diagram of a cross-sectional view of a portion of heater plate 300A including porous plug 310A formed in purge channel 242, in accordance with some embodiments. More specifically, porous plug 310A is a staggered porous plug formed in a staggered purge channel 242 to reduce direct line of sight between RF and ground. A staggered porous plug has a conical or tapered profiles with varying diameters as a function of height. The porosity of porous plug 310A can be selected to inhibit plasma formation, while allowing heat transfer fluid to reach the substrate support surface. Porous plug 310A can include any suitable material. For example, porous plug 310A can include a porous dielectric material. Porous plug 310A can be secured using any suitable bonding. For example, porous plug 310A can be bonded using a high-temperature adhesive (e.g., high-temperature glue).

FIG. 3B is a diagram of a cross-sectional view of a portion of heater plate 300B including porous plug 310B formed in purge channel 242, in accordance with some embodiments. More specifically, purge channel 242 is a counterbore hole and porous plug 310B is a formed in the counterbore hole. Porous plug 310B can be held in place with an adhesive that fills in vertical gaps between porous plug 310B and the wall of the counterbore hole. The porosity of porous plug 310B can be selected to inhibit plasma formation, while allowing heat transfer fluid to reach the substrate support surface. Porous plug 310B can include any suitable material. For example, porous plug 310B can include a porous dielectric material. Porous plug 310B can be secured using any suitable bonding. For example, porous plug 310B can be bonded using a high-temperature adhesive (e.g., high-temperature glue).

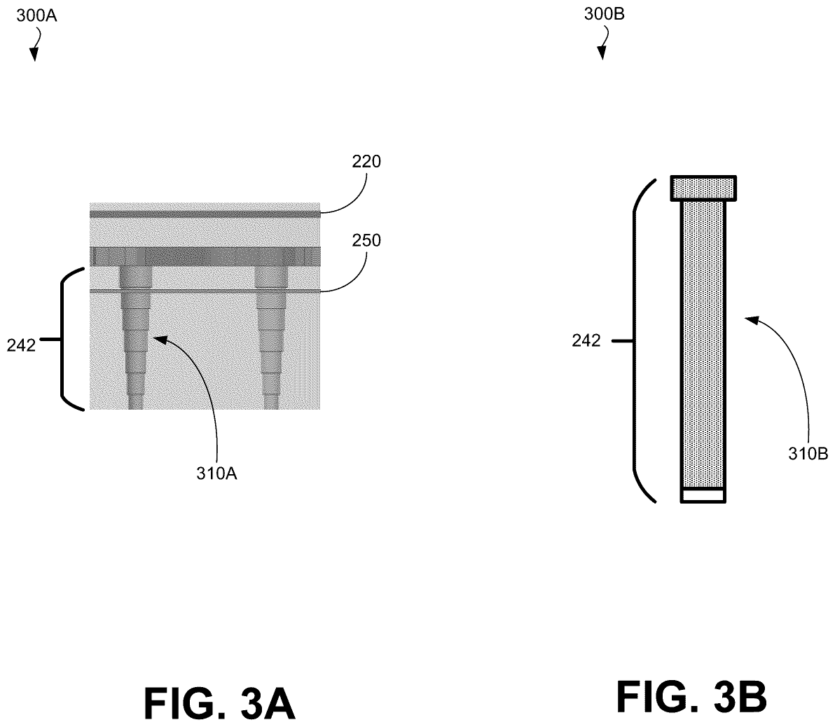

FIG. 4 is a flow chart of an example method 400 for fabricating heater assemblies having distributed purge channels, RF meshes and ground electrodes, in accordance with some embodiments. For example, method 400 can be performed to fabricate substrate support assembly 200A of FIG. 2A.

At block 410, a heater plate is obtained. The heater plate includes a set of components formed within a plate. The plate can be formed from a dielectric material. In some embodiments, the plate is formed from a ceramic material. For example, the plate can be formed from AlN, Al₂O₃, etc.

In some embodiments, obtaining the heater plate includes receiving a preformed heater plate. In some embodiments, obtaining the heater plate includes forming at least a portion of the heater plate. For example, forming at least a portion of the heater plate can include at least one of: embedding a heater electrode within the plate, forming a ground electrode within the heater plate, forming a set of distributed purge channels within the heater plate, embedding an RF mesh within the heater plate, or embedding an edge electrode within the heater plate.

In some embodiments, forming the set of distributed purge channels includes drilling through the plate (e.g., laser drilling). In some embodiments, forming the set of distributed purge channels includes forming at least one porous plug within at least one purge channel of the set of distributed purge channels. For example, a porous plug can be a staggered porous plug formed within a staggered hole corresponding to a purge channel. As another example, a porous plug can be formed within a counterbore hole corresponding to a purge channel. The porosity of a porous plug can be selected to inhibit plasma formation, while allowing heat transfer fluid to reach the substrate support surface. A porous plug can include any suitable material. For example, a porous plug can include a porous dielectric material. A porous plug can be secured using any suitable bonding. For example, a porous plug can be bonded using a high-temperature adhesive (e.g., high-temperature glue).

At block 420, the heater plate is connected to a shaft. Connecting the heater plate to the shaft can include connecting the set of components to an RF connector. In some embodiments the RF connector includes an RF coax connector including an RF feed that can enable symmetric RF delivery. For example, the RF coax connector can include an RF rod in contact with the RF mesh and an outer shield in contact with the ground electrode. Further details regarding blocks 410-420 are described above with reference to FIGS. 1-3B.

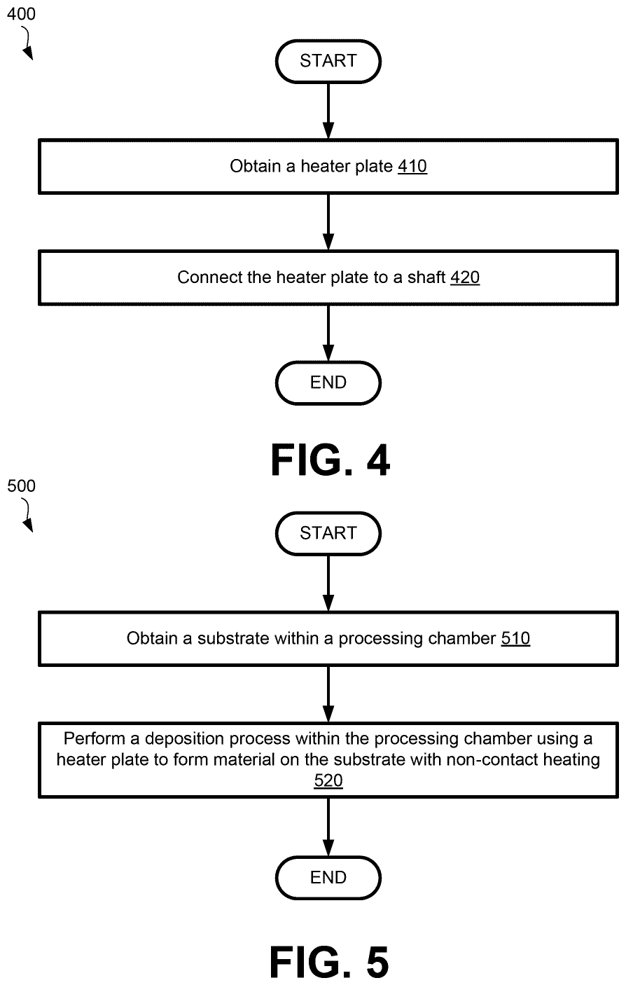

FIG. 5 is a flow chart of an example method 500 for processing a substrate within a processing chamber using a substrate support assembly including a heater plate with distributed purge channels, an RF mesh and a ground electrode, in accordance with some embodiments. For example, method 500 can be performed within system 100 of FIG. 1.

At block 510, a substrate is obtained within a processing chamber. The processing chamber can include a showerhead assembly for providing process gases into the processing chamber. For example, the processing chamber can be processing chamber 105 of FIG. 1 and the substrate can be substrate 140 of FIG. 1. Obtaining the substrate can include placing the substrate on a set of lift pins disposed on the showerhead assembly.

At block 520, a deposition process is performed within the processing chamber using a heater plate to form material on the substrate with non-contact heating. The heater plate can be disposed on a shaft. For example, the heater plate can be heater plate 120 described above with reference to FIGS. 1-3B. In some embodiments, performing the deposition process includes performing a backside deposition process to form a material on a backside of the substrate. For example, the backside deposition process can be a PECVD process (e.g., CCP process). Performing the backside deposition process can include lowering the heater plate toward a frontside of the substrate to provide a gap between the heater plate and the frontside of the substrate, and initiating the backside deposition process. The gap enables non-contact heating of the substrate using a set of heater electrodes of the heater plate. The deposition process can be performed by generating plasma in a region between the backside of the substrate and the showerhead assembly. Unwanted process gases can be purged from the frontside of the substrate using a set of distributed purge channels formed within the heater plate. The heater plate can further include a ground electrode to prevent plasma light up near the shaft and to shield the set of heater electrodes from RF, and an RF mesh to enable bias capability. Symmetric RF delivery can be enabled by an RF connector formed through the shaft to the heater plate (e.g., RF coax connector). In some embodiments, the heater plate further includes an edge electrode for plasma profile control. Further details regarding blocks 510-520 are described above with reference to FIGS. 1-4.

The preceding description sets forth numerous specific details such as examples of specific systems, components, methods, and so forth, in order to provide a good understanding of several embodiments of the present invention. It will be apparent to one skilled in the art, however, that at least some embodiments of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±25%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the invention should, therefore, be determined with reference to the appended claims, along with the full scope of equivalents to which such claims are entitled.

What is claimed is:

1. A substrate support assembly comprising:
a heater plate comprising a dielectric material;
a heater electrode embedded within the heater plate;
a set of distributed purge channels formed within the heater plate, wherein the set of distributed purge channels provides a set of gas flow paths to equalize a gas flow from within the heater plate and direct the gas flow in a direction below the heater plate;
a ground electrode embedded within the heater plate; and
a radio frequency (RF) mesh embedded within the heater plate.

2. The substrate support assembly of claim 1, wherein the dielectric material is a ceramic material.

3. The substrate support assembly of claim 1, further comprising a shaft, wherein the heater plate is disposed on the shaft.

4. The substrate support assembly of claim 3, further comprising an RF connector formed within the shaft and coupled to the heater plate.

5. The substrate support assembly of claim 4, wherein RF connector is an RF coax connector comprising an outer shield and an RF rod.

6. The substrate support assembly of claim 1, further comprising a porous plug disposed within a purge channel of the set of distributed purge channels.

7. The substrate support assembly of claim 1, further comprising an edge electrode embedded within the heater plate.

8. A system comprising:
a showerhead assembly comprising a set of lift pins to receive a substrate over the showerhead assembly, and a showerhead to deliver one or more process gases to perform a deposition process to deposit a material on a backside of the substrate; and
a substrate support assembly disposed above the showerhead assembly, the substrate support assembly comprising:
a shaft;
a heater plate disposed on the shaft and comprising a dielectric material;
a heater electrode embedded within the heater plate;
a set of distributed purge channels formed within the heater plate, wherein the set of distributed purge channels provides a set of gas flow paths to equalize a gas flow from within the heater plate and direct the gas flow in a direction below the heater plate;
a ground electrode embedded within the heater plate; and
a radio frequency (RF) mesh embedded within the heater plate.

9. The system of claim 8, wherein the dielectric material is a ceramic material.

10. The system of claim 8, wherein the substrate support assembly further comprises an RF connector formed within the shaft and coupled to the heater plate.

11. The system of claim 10, wherein RF connector is an RF coax connector comprising an outer shield and an RF rod.

12. The system of claim 8, wherein the substrate support assembly further comprises a porous plug disposed within a purge channel of the set of distributed purge channels.

13. The system of claim 8, wherein the substrate support assembly further comprises an edge electrode embedded within the heater plate.

14. The system of claim 8, wherein the deposition process is a capacitively coupled plasma (CCP) deposition process.

15. A method comprising:
obtaining a substrate within a processing chamber; and
performing a deposition process within the processing chamber using a substrate support assembly to form material on the substrate with non-contact heating, the substrate support assembly comprising:
a heater plate comprising a dielectric material;
a heater electrode embedded within the heater plate;
a set of distributed purge channels formed within the heater plate, wherein the set of distributed purge channels provides a set of gas flow paths to equalize a gas flow from within the heater plate and direct the gas flow in a direction below the heater plate;
a ground electrode embedded within the heater plate; and
a radio frequency (RF) mesh embedded within the heater plate.

16. The method of claim 15, wherein obtaining the substrate comprises placing the substrate on a set of lift pins disposed on a showerhead assembly of the processing chamber.

17. The method of claim 15, wherein the deposition process is a capacitively coupled plasma (CCP) deposition process.

18. The method of claim 15, wherein the deposition process is a backside deposition process to form the material on a backside of the substrate.

19. The method of claim 18, wherein performing the deposition process comprises:
lowering the heater plate toward a frontside of the substrate to provide a gap between the heater plate and the frontside of the substrate; and
initiating the backside deposition process.

20. The method of claim 15, wherein the substrate support assembly further comprises an edge electrode embedded within the plate.
